(19) United States
(12) Patent Application Publication
(10) Pub. No.: US 2018/0019169 A1
(43) Pub. Date: Jan. 18, 2018

(54) BACKING SUBSTRATE STABILIZING DONOR SUBSTRATE FOR IMPLANT OR RECLAMATION

(71) Applicant: QMAT, Inc., Santa Clara, CA (US)

(72) Inventor: Francois J. HENLEY, Saratoga, CA (US)

(21) Appl. No.: 15/643,370

(22) Filed: Jul. 6, 2017

Related U.S. Application Data
(60) Provisional application No. 62/361,468, filed on Jul. 12, 2016.

(51) Int. Cl. H01L 21/78; H01L 21/02; H01L 21/762; H01L 21/683; H01L 33/00; H01L 23/373

(52) U.S. Cl. CPC H01L 21/7813; H01L 21/6835; H01L 33/0062; H01L 21/02032; H01L 21/76254; H01L 2221/68368; H01L 23/373

(57) ABSTRACT

A donor substrate in a layer transfer process, is stabilized by attaching a backing substrate. The backing substrate allows thermal and mechanical stabilization during high-power implant processes. Upon cleaving the donor substrate to release a thin layer of material to a target, the backing substrate prevents uncontrolled release of internal stress leading to buckling/fracture of the donor substrate. The internal stress may accumulate in the donor substrate due to processes such as cleave region formation, bonding to the target, and/or the cleaving process itself, with uncontrolled bow and warp potentially precluding reclamation/reuse of the donor substrate in subsequent layer transfer processes. In certain embodiments the backing substrate may exhibit a Coefficient of Thermal Expansion (CTE) substantially matching, or complementary to, that of the donor substrate. In some embodiments the backing structure may include a feature such as a lip.

### CROSS-REFERENCE TO RELATED APPLICATION

The instant nonprovisional patent application claims priority to U.S. Provisional Patent Appl. No. 62/361,468 filed Jul. 12, 2016 and incorporated by reference herein in its entirety for all purposes.

### BACKGROUND

Conventional techniques for manufacturing electronic devices, may involve the formation and manipulation of thin layers of materials. One example of such manipulation is the transfer of a thin layer of material from a first (donor) substrate to a second (target) substrate. This may be accomplished by placing a face of the donor substrate against a face of the target substrate, and then cleaving the thin layer of material along a sub-surface cleave plane formed in the donor substrate.

The donor substrate may comprise valuable, high quality crystalline material that is expensive to produce and may contain devices already processed onto a face. Thus, following such a layer transfer process, the donor substrate may be sought to be reclaimed for subsequent use in further layer transfer efforts. Accordingly, there is a need in the art for methods and apparatuses of processing a donor substrate to allow for its reclamation for subsequent layer transfer. There is also a need to mechanically and thermally stabilize a donor substrate to allow it to be subjected to high-power implant processes.

### SUMMARY

A donor substrate in a layer transfer process, is stabilized by attaching a backing substrate. When utilized within a high-power implant process, the assembly (donor and backing substrate) has enhanced mechanical stability and thermal heat spreading capabilities to allow for optimized backside heat extraction through convection or conduction mechanisms. Upon cleaving the donor substrate to release a thin layer of material to a target, the backing substrate prevents uncontrolled release of internal stress leading to buckling/fracture of the donor substrate. The internal stress may accumulate in the donor substrate due to processes such as cleave region formation, bonding to the target, and/or the cleaving process itself, with uncontrolled buckling/fracture potentially precluding reclamation/reuse of the donor substrate in subsequent layer transfer processes. In certain embodiments the backing substrate may exhibit a Coefficient of Thermal Expansion (CTE) substantially matching, or complementary to, that of the donor substrate. In some embodiments the backing structure may include a feature such as a lip, constraining lateral expansion of the donor substrate (e.g., in response to the application of thermal energy) and allowing mechanical fixturing of the assembly onto equipment such as a polishing or implant tool.

### BRIEF DESCRIPTION OF THE DRAWINGS

FIGS. 1A-1F show simplified cross-sectional views of a process flow according to an embodiment.

FIG. 2 shows a simplified cross-sectional view of a possible donor substrate/backing substrate combination.

FIG. 3 shows a simplified view of a fabrication process involving the reclamation of a GaN substrate.

FIG. 3A is a simplified view showing the Ga face and N face of a GaN substrate.

FIG. 4 illustrates a simplified flow diagram of a reclamation process according to an embodiment.

FIG. 5 plots thermal conductivity versus gap.

### DETAILED DESCRIPTION

The process of transferring thin layers of material from a donor substrate to a target, may involve the formation of stress in the donor. For example, certain embodiments may employ bonding the donor substrate to a target, followed by controlled cleaving along a cleave region formed at a depth in the donor substrate.

Such a cleave region may result from the implantation of particles (e.g., hydrogen ions) into a face of the donor substrate. The resulting controlled cleaving may call for the application of energy to the donor substrate to initiate and/or propagate cleaving along the cleave region, leaving a thin film of transferred material remaining bonded to the target.

Stress in the donor may arise from a variety of sources. One possible source of stress may be formation of the cleave region. In particular, the energetic implantation of particles into the donor substrate creates a subsurface cleave region different from the surrounding material. This may give rise to stress at surface and subsurface locations.

In addition, it is noted that the cleave region itself may not be formed under uniform conditions, leading to internal stress. For example, edge/initiation portions of a cleave region may receive higher doses of implanted particles than other portions of the cleave region, leading to further stress within the donor substrate.

Another possible source of stress in the donor substrate may be the bonding process. In particular, the donor substrate may be exposed to conditions such as elevated temperatures, reduced pressures, and/or external energies (e.g., plasma) in order to accomplish bonding the implanted face of the donor substrate to the target. These conditions can give rise to internal stress being created within the donor substrate.

Still other sources of possible stress in the donor substrate may arise from the cleaving process itself. In particular, one or more forms of energy may be applied to the donor in order to release the thin layer along the cleave region. Examples of such energy can include but are not limited to thermal energy (e.g., an electron beam), optical energy (e.g., a laser), pneumatic energy (e.g., a pressurized gas jet), hydraulic energy (e.g., a pressurized water jet), and mechanical energy (e.g., application of a blade).

Moreover, certain controlled cleaving processes may involve an initiation phase creating a cleave front, followed by a propagation phase to cause the cleave front to migrate across the substrate, ultimately resulting in the complete detachment of a thin layer of material from the donor substrate. In such embodiments the same (or different) types of energy may be applied (at the same or different magnitudes) for cleave initiation, as are subsequently used to propagate a cleave front that has been formed.

Finally, it is noted that cleaving processes may operate differently in certain portions of the substrate than others. For example, the existence of a bevel in the target substrate may preclude contact with edge regions of the donor substrate. Upon cleaving, this can result in edge portions of the donor remaining bound to the donor rather than being transferred to the target. This and other phenomena associated with cleaving, can introduce stress internal to the donor substrate.

Following a cleaving process, it may be desired to reclaim the remainder of the donor substrate for subsequent reuse in the transfer of additional thin films. However, internal stress that has developed within a donor substrate due to one or more of the above processes (e.g., cleave region formation, bonding, cleave initiation/propagation), can interfere with efficient reclamation.

In particular, internal stress accumulated within the donor substrate can find relief by uncontrolled roughening, buckling, or even fracture of the donor material. This in turn can render the donor substrate unsuited for future use.

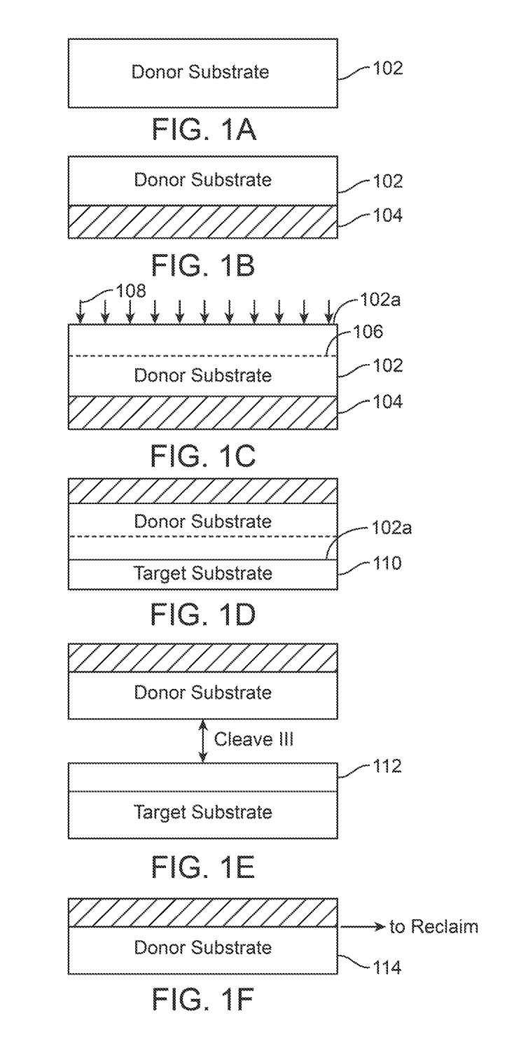

Accordingly, in order to provide stress relief and stabilization, embodiments propose the attachment of a backing substrate to the donor substrate. FIGS. 1A-1F are simplified cross-sectional views of flow diagram showing an embodiment of this process.

FIG. 1A shows the donor substrate 102. In this initial state, the donor substrate is relatively homogenous and substantially unaffected by previous external forces that might give rise to internal stresses.

FIG. 1B shows attachment of the backing substrate 104 to the donor substrate. In certain embodiments this attachment may be accomplished utilizing reversible processes, wherein it is foreseen that the backing substrate will ultimately be released from the donor at some future point (e.g., following the transfer of several thin layers or after each transfer). Examples of such reversible processes can include but are not limited to reversible adhesives, solder, and lift off systems such as Laser Lift Off (LLO) or Thermal Lift Off (TLO).

In alternative embodiments, attachment of the backing substrate to the donor may be accomplished under irreversible conditions. There, it is not foreseen that the backing substrate will be released from the donor. Examples of such generally irreversible processes can include but are not limited to permanent adhesives, thermo-compression bonding, Transient Liquid-Phase (TLP) bonding and fit-based ceramic bonding.

FIG. 1C shows a subsequent step, wherein a cleave region 106 is formed in the donor substrate. As previously mentioned, this cleave region may be formed by the implantation of energetic particles 108 into the face 102a of the donor substrate that is not attached to the backing substrate.

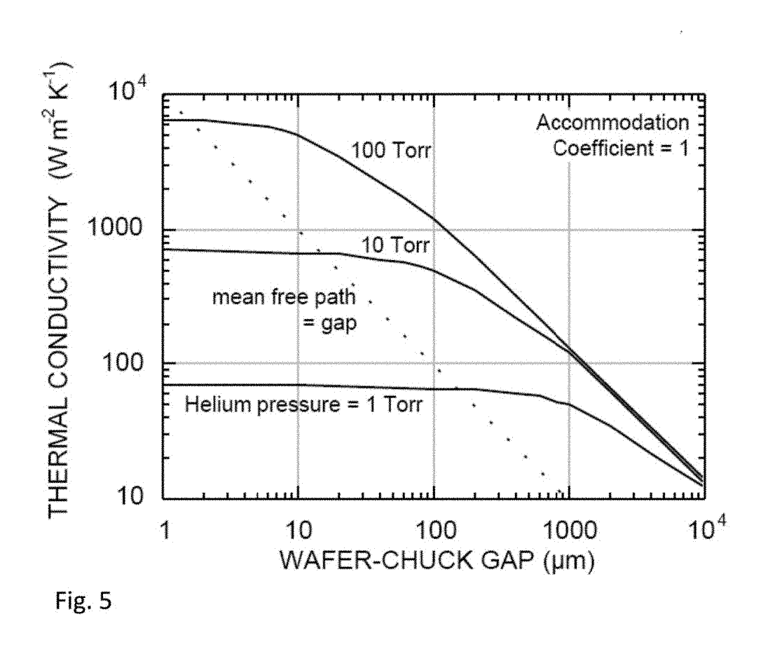

Within an implant process performed under vacuum, the donor substrate/backing substrate assembly can allow for higher power density implants with less temperature excursion. These benefits occur by having a stiffer assembly that allows for more gas cooling backpressure and/or mechanical pressure to be applied on the backside for thermal heat dissipation. For example, at a 3×10¹⁷ H+/cm² dose with about 100 pieces of 2-inch GaN substrates over a 4,000 cm² area scanned by a 150 keV, 60 mA proton beam, the areal power density will be about 2.25 W/cm². If a temperature rise of no more than 40° C. temperature is desired from the assembly to implant cooling plate, a thermal conductance of 0.056 W/cm²-K is required. Assuming no more than 25 um mechanical bending in the center, a backside pressure of 10 Torr is required (see FIG. 5). This will in turn determine the required mechanical stiffness of the assembly. For a disk under uniform pressure on one face and assuming the assembly constitutes a single mechanical assembly with similar Young's Modulus, the maximum deflection equation is:

Center gap=0.696pr⁴/Et³ (1)

Where p=pressure in Pa, r=wafer radius, E=Young's Modulus of Elasticity, t=assembly thickness.

For this configuration, the required thickness is less than the GaN substrate thickness which is typically 400-500 μm. The conclusion is that for this application, reclamation and general handling of fragile GaN substrates in a production environment would dictate the required backing plate thickness. A 1 mm Mo plate would thus be sufficient to satisfy the implant conditions above. A slightly larger diameter of the backing plate would allow edge clamping of the assembly without contacting the 2″ (50.8 mm) GaN substrate.

For a deep implant using a high-power implant beam impinging on 300 mm silicon substrates, the minimum backing plate thickness can be substantial to avoid excessive plate bending during backside gas application. As an example, a deep (750 keV) proton implant at 60 mA over 4 300 mm silicon wafers would apply a thermal load of 45 kW over 4,000 cm² area or about 11.2 W/cm². Assuming no more than 100° C. temperature rise, a thermal conductance of 0.112 W/cm²-K is required. According to FIG. 5, approximately 20 T of backpressure is required and the gap cannot exceed about 20 μm. Assuming a silicon backing plate is added to the 300 mm wafer (E_{Si}130 GPa), the plate assembly thickness should be on the order of 7.1 mm. The backing plate would therefore have to be on the order of 6.4 mm (a SEMI specification 300 mm substrate thickness is about 775 μm). Edge clamping can be made easier by selecting a backing plate diameter slightly larger than the 300 mm silicon substrate. For certain applications where post-implant processes cannot accommodate the backing plate assembly, attaching the 300 mm substrate may be preferably made using a reversible bond that allows separation of the assembly after implant.

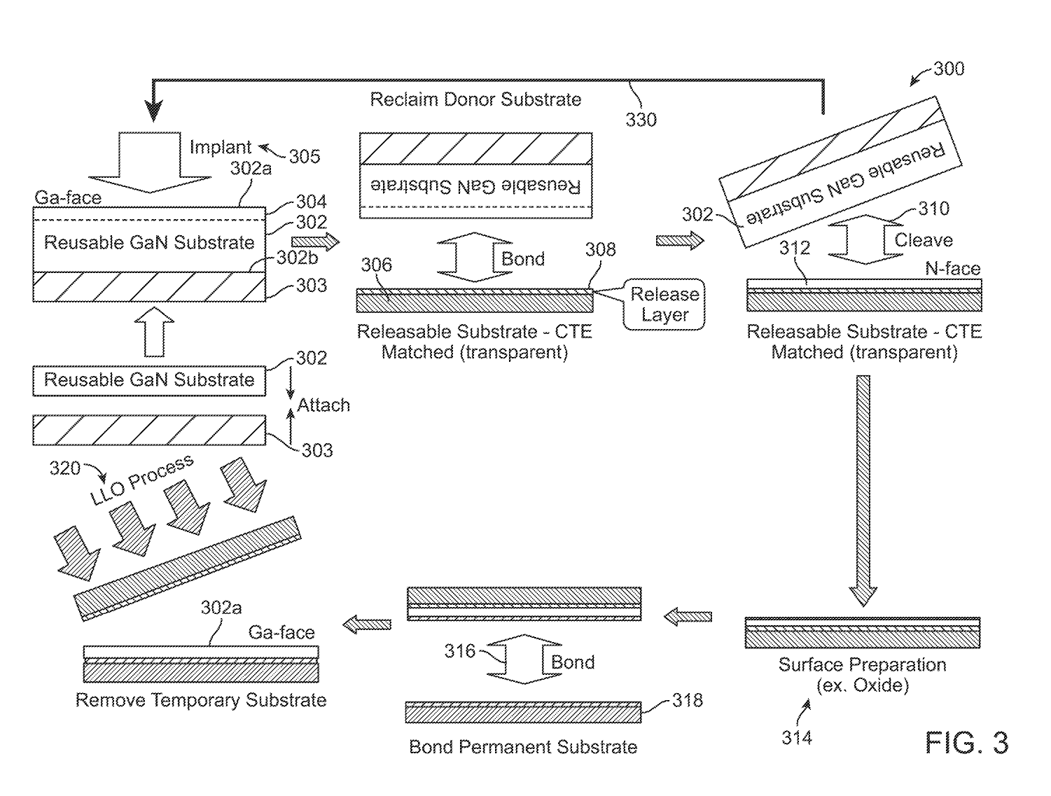

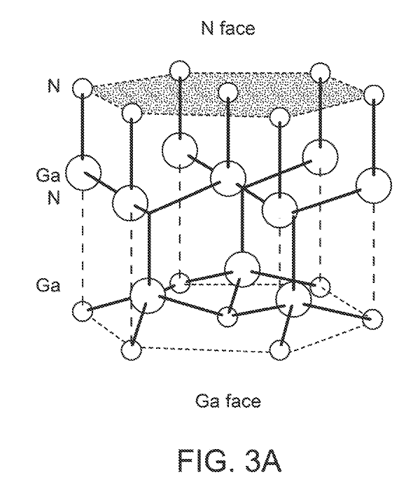

FIG. 1D shows the next step, wherein the implanted face 102a is bound to a target substrate 110. This bonding can take a variety of forms, including the use of a release layer as described further below in connection with FIG. 3.

FIG. 1E shows the cleaving process. Here, applied energy interacting with the cleave region results in a cleave 111 of the donor substrate material. This cleave transfers the thin film of donor material 112 to the surface of the target substrate.

FIG. 1F shows the post-cleaving state of the donor substrate. In particular, the backing substrate remains attached, providing physical support to resist buckling/fracture of the donor substrate in order to release internal stress accumulated therein. While the exposed face of the donor substrate may exhibit some roughness 114, that roughness does not rise to the level of buckling or fractures that could render the donor substrate unsuited for reclamation.

The donor substrate supported by the backing substrate is now available for reclamation processes. Examples of such reclamation can include but are not limited to grinding, polishing, plasma exposure, wet chemical exposure, and/or thermal exposure.

The presence of the backing substrate supporting the donor substrate, may further serve to stabilize the latter during such reclamation processing. That is, stress arising from the application of energy to prepare the donor substrate surface for subsequent implant, may be addressed by the backing substrate to prevent uncontrolled stress release giving rise to buckling, fracture, etc.

It is further noted that the backing substrate should be compatible with exposure to the conditions under which reclamation is to take place. For example, where reclamation involves exposure to a plasma, the use of certain kinds of metal for the backing substrate may be discouraged in order to avoid arcing. In another example, where the reclamation involves etching conditions, the backing substrate should not comprise a material susceptible to degradation by repeated exposure to the etching conditions, to the point that it is unable to perform its stabilizing function.

In most applications, the backing substrate may comprise a material matching in thermal expansion coefficient over the temperature range of interest. This would limit deformations and temperature induced stresses that can lower yield and achievable specifications such as surface flatness. Materials such as molybdenum, tungsten, aluminum nitride, Mullite, sapphire, and CTE-matched glasses could satisfy criteria to be used as a backing plate material. Apart from mechanical flatness, CTE-matching and stiffness, making the backing plate slightly larger in diameter can also have practical benefits. In some applications this may also be advantageous to choose a material which is electrically conductive. To secure the backing plate assembly for implant or polishing operations without touching the GaN surface, a lip of backing material extending from the GaN edge would allow mechanical clamping. For most applications, a lip of millimeter scale would be sufficient.

One example of the use of a backing substrate for a donor, is now given in connection with the fabrication of hetero-structure layers and 3D-IC semiconductor devices. In some high-performance digital applications, an InGaAs layer is transferred onto a silicon substrate to form a 3D monolithic integration assembly. The implant energy in this application could be on the order of 50-300 keV. Also, in some 3D-IC stacking processes, high-energy proton implantation of 300 keV to 1 MeV and even 2 MeV are used to position a cleave plane well below the device layers to allow cleaving and transfer of a device layer onto a target substrate which collects multiple layers to form a 3D-IC structure. For both applications, the use of a backing substrate would allow for high-power implantation and efficient manufacturing without overheating the donor substrate.

One example of the use of a backing substrate for a donor, is now given in connection with the fabrication of an opto-electronic device. Specifically, semiconducting materials find many uses, for example in the formation of logic devices, solar cells, and increasingly, illumination.

One type of semiconductor device that can be used for illumination is the high-brightness light emitting diode (HB-LED). In contrast with traditional incandescent or even fluorescent lighting technology, HB-LED's offer significant advantages in terms of reduced power consumption and reliability.

An optoelectronic device such as a HB-LED may rely upon materials exhibiting semiconductor properties, including but not limited to type III/V materials such as gallium nitride (GaN) and GaAs is available in various degrees of crystalline order. However, these materials are often difficult to manufacture.

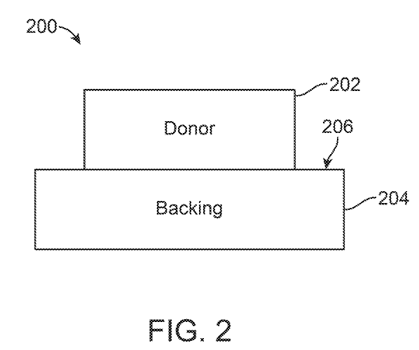

Accordingly, FIG. 2 shows a simplified example of a substrate combination 200 comprising a donor substrate 202 that is attached to a backing substrate 204. The donor substrate 202 comprises high-quality GaN material, suitable for use in the fabrication of a HB-LED device.

The backing substrate 204 comprises a material that is compatible with the high-quality GaN material of the donor substrate. In certain embodiments, the backing substrate may exhibit a Coefficient of Thermal Expansion (CTE) that substantially matches, or is complementary to, that of the donor substrate.

Specifically, the backing substrate may exhibit properties that serve to accommodate and/or relieve internal stress arising in the donor substrate as a result of being subjected to one or more reclamation processes conducted in various environments. Examples of such reclamation processes can include but are not limited to, grinding, polishing, plasma or ion beam assisted etching, wet chemistry, thermal, vacuum, implantation, and others.

According to certain embodiments, the backing structure may include a feature such as a lip 206. A lip feature can serve to hold the donor/backing substrate assembly onto a platen or holder without contacting or covering the front face of the donor substrate. The backing structure also has a thickness, selected to satisfy the larger of a minimum thickness requirement from implant or reclamation processes.

Examples of possible approaches for fabricating a template suitable for high quality GaN growth, are described in U.S. provisional patent application No. 62/181,947 filed Jun. 19, 2015 (“the '947 provisional application”), and in U.S. nonprovisional patent application Ser. No. 15/186,184 filed Jun. 17, 2016, both of which are incorporated by reference in their entireties herein for all purposes. FIG. 3 shows a simplified view of one fabrication process 300 to form a permanent substrate offering a template for the subsequent growth of high quality GaN for opto-electronic applications.

In this example, a donor substrate 302 comprises high-quality GaN material. A backing substrate 303 is attached to the donor substrate.

A cleave region 304 is located at a sub-surface region of the donor substrate. This cleave region may be formed, for example, by the energetic implantation 305 of particles such as hydrogen ions, into one face of the GaN donor substrate.

Here, it is noted that the crystalline structure of the GaN donor substrate, results in it having two distinct faces: a Ga face 302a, and an N face 302b. FIG. 3A is a simplified view illustrating the internal structure of a GaN substrate, showing the Ga face and the N face.

In a next step of the process of FIG. 3, the implanted Ga face of the GaN substrate is bonded to a releasable substrate 306 bearing a release layer 308. The material of the releasable substrate may be selected such that its Coefficient of Thermal Expansion (CTE) substantially matches that of the GaN. As discussed later in detail below, the material of the releasable substrate may also be selected to be transparent to incident laser light as part of a Laser Lift Off (LLO) process. In connection with these desired properties, a releasable substrate comprising glass may be used.

The release layer may comprise a variety of materials capable of later separation under controlled conditions. As described in the '947 provisional application, candidate releasable materials can include those undergoing conversion from the solid phase to the liquid phase upon exposure to thermal energy within a selected range. Examples can include soldering systems, and systems for Thermal Lift Off (TLO).

In certain embodiments the release system may comprise silicon oxide. In particular embodiments this bond-and-release system can be formed by exposing the workpieces to oxidizing conditions. In some embodiments this bond-and-release system may be formed by the addition of oxide, e.g., as spin-on-glass (SOG), or other spin on material (e.g., XR-1541 hydrogen silsesquioxane electron beam spin-on resist available from Dow Corning), and/or SiO₂ formed by sputtering or Plasma Enhanced Chemical Vapor Deposition (PECVD) techniques.

In a next step of the process of FIG. 3, energy is applied to cleave 310 the GaN substrate along the cleave region, resulting in a separated layer of GaN material 312 remaining attached to the release layer and the releasable substrate. Examples of such cleaving processes are disclosed in U.S. Pat. No. 6,013,563, incorporated by reference in its entirety herein.

Following cleaving of the GaN, FIG. 3 shows a number of subsequent steps that are performed in order to create the template for high-quality GaN growth. These steps include surface preparation 314 of the separated GaN layer (e.g., the formation of an oxide), bonding 316 the separated GaN layer to a permanent substrate 318, and finally the removal of the releasable substrate utilizing the release layer (e.g., utilizing a LLO process 320), to result in the N face of the separated GaN layer being bonded to the permanent substrate.

The Ga face is exposed and available for growth of additional high quality GaN material under desired conditions. Additional GaN may be formed by Metallo-Organic Chemical Vapor Deposition (MO-CVD), for example. That additional thickness of GaN material (with or without the accompanying substrate and/or dielectric material) may ultimately be incorporated into a larger optoelectronic device structure (such as a HB-LED).

Returning to the third (cleaving) step shown in FIG. 3, separation of the GaN film results in the valuable GaN donor substrate comprising high quality GaN material, being available for re-use in order to create additional template structures for growth of additional high quality GaN. The donor substrate can be exposed to additional implantation, and then bonding to another releasable substrate.

However, before such re-use can properly take place, the GaN donor substrate may need to first be reclaimed so that it is suitable for the intended processing. In particular, the Ga face of the donor substrate may exhibit properties such as surface roughness, defects, and/or non-planarity resulting from the previous cleaving step, that render it unsuitable for immediate implantation and bonding.

Accordingly, subjecting the donor substrate to reclamation may permit its re-use. Donor substrate reclamation procedures may comprise exposure to one or more of the following environments: grinding, polishing, plasma or ion beam assisted etching, wet chemistry, thermal, vacuum, and others.

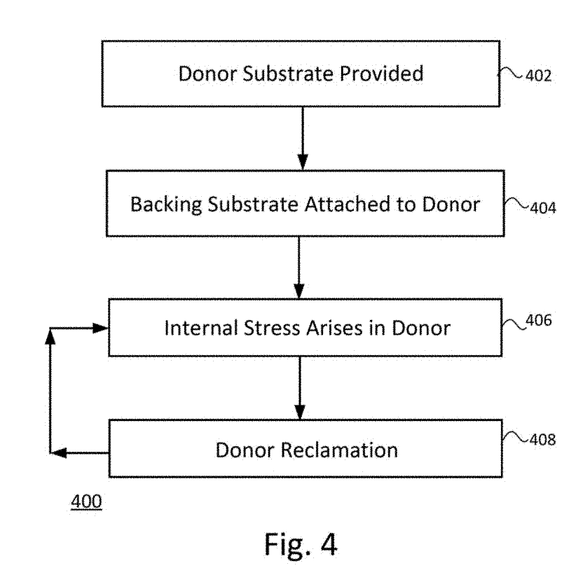

FIG. 4 is a simplified flow diagram illustrating a process 400 according to an embodiment. In a first step 402, a donor substrate is provided.

In a second step 404, a backing substrate is attached to the donor substrate. In a third step 406, the donor substrate attached to the backing substrate, is exposed to conditions giving rise to internal stress. The presence of the backing substrate serves to stabilize the donor substrate under these conditions, thereby allowing reclamation of the donor substrate in connection with subsequent processing.

Such a reclamation is shown as step 408 in FIG. 4. As shown by the loop, that reclamation may be followed in turn by processing giving rise to internal stress in the donor substrate (e.g., implantation, bonding, cleaving, etc.).

When mechanical processes are used for reclamation such as grinding, polishing and CMP, the donor assembly (backing and donor substrates) may need to meet flatness and stiffness requirements. Depending on the stresses generated by the prior processes, a donor substrate could exhibit excessive bow and warp that can result in non-uniform reclamation of the donor surface. After attaching a backing substrate of minimum stiffness, the donor surface is stabilized in flatness and can be reclaimed in a manner that meets surface specifications. As an example, a 2″ diameter GaN substrate of 470 um thickness was modeled using finite element analysis. The GaN substrate was given an initial bow value of 74 um (center to edge bow across the principal face). This level of bow is representative of a stress level of approximately 700 MPa extending 5 um into the GaN substrate from the top surface. This represents a stress state of the GaN substrate that must be removed through reclaim. Attaching a backing substrate can allow uniform lapping, polishing and CMP processes to remove this stress layer by lowering the bow value to about the same order as the target layer removal value (in this case about 5 um). When bonded to a 3 mm Mo backing substrate, the bow is reduced from 74 um to 3.9 um. A 5 mm Mo backing substrate would reduce the bow to 1.6 um. Bow reduction of this magnitude would make the reclamation processes uniform and predictable.

Returning to FIG. 3, the particular embodiment illustrated in that figure results in the N face of the GaN layer being bonded to the permanent substrate, with the Ga face of the detached GaN layer exposed for further processing. This is because the Ga face has traditionally proven more amenable to the growth of high quality GaN than the N face.

However, other embodiments are possible. For example some applications (e.g., power electronics) may call for growth of GaN material from the N face, rather than from the Ga face. Incorporated by reference herein for all purposes are the following articles: Xun Li et al., “Properties of GaN layers grown on N-face free-standing GaN substrates”, Journal of Crystal Growth 413, 81-85 (2015); A. R. A. Zauner et al., “Homo-epitaxial growth on the N-face of GaN single crystals: the influence of the misorientation on the surface morphology”, Journal of Crystal Growth 240, 14-21 (2002). Accordingly, template blank structures of some embodiments could feature a GaN layer having an N face that is exposed, rather than a Ga face. Alternatively, an N face donor assembly could be used to fabricate a Ga face final substrate when bonded to a final substrate instead of a releasable transfer substrate as in FIG. 2.

Such embodiments could be particularly amenable to the use of a backing substrate to stabilize the donor substrate after cleaving. In particular, the N-face of a GaN crystal is more chemically reactive compared to the Ga-face. Accordingly, the presence of a backing substrate could serve to flatten the assembly and reduce undesired enhanced etching of surfaces due to bow and warp high areas acting upon the CMP processes.

While the above discussion has focused upon the use of a backing substrate for GaN transfer processes, embodiments are not limited to such approaches. Certain embodiments may employ a backing substrate for fabrication processes involving a different Group III/V material such as GaAs. In particular embodiments, sapphire may be particularly suited to serve as a backing substrate for the transfer of GaAs material from a donor.

While the above is a full description of the specific embodiments, various modifications, alternative constructions and equivalents may be used. Although the above has been described using a selected sequence of steps, any combination of any elements of steps described as well as others may be used. Additionally, certain steps may be combined and/or eliminated depending upon the embodiment. Furthermore, the particles of hydrogen can be replaced using co-implantation of helium and hydrogen ions or deuterium and hydrogen ions to allow for formation of the cleave region with a modified dose and/or cleaving properties according to alternative embodiments. Still further, the particles can be introduced by techniques such as a diffusion process rather than an implantation process. Of course there can be other variations, modifications, and alternatives. Therefore, the above description and illustrations should not be taken as limiting the scope of the present invention which is defined by the appended claims.

What is claimed is:

1. A method comprising:
providing a donor substrate comprising a first face and a second face;
attaching the first face to a backing substrate;
processing the donor substrate to create an internal stress;
bonding the second face to a target substrate;
cleaving the donor substrate in a cleave region to transfer a layer of material to the target substrate, with remaining material of the donor substrate staying attached to the backing substrate; and
reclaiming the remaining material while the first face of the donor substrate stays attached to the backing substrate.

2. A method as in claim 1 wherein the cleave region is formed by implanting particles into the donor substrate attached to the backing substrate, and the internal stress arises from the implanting.

3. A method as in claim 1 wherein the backing substrate exhibits a coefficient of thermal expansion similar to a coefficient of thermal expansion of the donor substrate.

4. A method as in claim 1 wherein an assembly comprising the donor substrate bonded to the backing substrate facilitates an implantation process, the cleaving, or the reclaiming.

5. A method as in claim 1 wherein the backing substrate clamps an edge of the donor substrate to restrain expansion of the donor substrate.

6. A method as in claim 1 wherein the reclaiming comprises thermal exposure.

7. A method as in claim 1 wherein the reclaiming comprises chemical exposure.

8. A method as in claim 7 wherein the chemical exposure comprises etching.

9. A method as in claim 6 wherein the chemical exposure comprises chemical mechanical polishing.

10. A method as in claim 1 wherein the reclaiming comprises grinding.

11. A method as in claim 1 wherein the reclaiming comprises plasma exposure.

12. A method as in claim 1 wherein the donor substrate comprises GaN.

13. A method as in claim 12 wherein the first face comprises a Ga face of the GaN donor substrate.

14. A method as in claim 12 wherein the first face comprises a N face of the GaN donor substrate.

15. A method as in claim 1 wherein the backing substrate comprises a lip.

16. A method as in claim 1 wherein the donor substrate comprises GaAs.

17. A method as in claim 16 wherein the backing substrate comprises sapphire.
